(19) United States
(12) Patent Application Publication
(10) Pub. No.: US 2019/0219637 A1
(43) Pub. Date: Jul. 18, 2019

(54) ELECTRICAL CIRCUIT TESTING DEVICE AND METHOD

(71) Applicant: One Step Power Solutions, Inc., Houston, TX (US)

(72) Inventor: Mark Craig, Houston, TX (US)

(21) Appl. No.: 16/248,906

(22) Filed: Jan. 16, 2019

Related U.S. Application Data
(60) Provisional application No. 62/618,103, filed on Jan. 17, 2018.

(51) Int. Cl. G01R 31/327

(52) U.S. Cl. CPC G01R 31/3277

(57) ABSTRACT

A circuit testing apparatus includes at least one resistance wire enclosed in a housing and connectable to a pole of a power distribution system having at least one isolation device therein. The resistance wire has electrical conductivity, length and diameter such that a maximum current in the resistance wire at initiation of burn through of the resistance wire is above a trip current of the at least one isolation device and below a current sufficient to damage any component along the pole of the power distribution system. In some embodiments, the housing includes a vent arranged to enable escape of heated gas therefrom and prevent escape of any hot particles resulting from burn through of the resistance wire.

### CROSS REFERENCE TO RELATED APPLICATIONS

Priority is claimed from U.S. Provisional Application No. 62/618,103 filed on Jan. 17, 2018, which application is incorporated herein by reference in its entirety.

### STATEMENT REGARDING FEDERALLY SPONSORED RESEARCH OR DEVELOPMENT

Not Applicable

### NAMES OF THE PARTIES TO A JOINT RESEARCH AGREEMENT

Not Applicable.

### BACKGROUND

This disclosure relates to the field of electrical circuit testing apparatus and methods. More specifically, the disclosure relates to apparatus and methods for testing circuit isolation devices for multiple electrical power generators used to operate a multiple electrically powered devices using interconnected power generation and load circuits.

Industrial electric power systems include multiple electrically powered devices powered by multiple electric power generators electrically connected to respective power distribution circuits. In such industrial electric power systems, each of a plurality of electric power generators (or alternators) are electrically connected to the power distribution circuits. The foregoing arrangement allows load sharing among subsets of or all of the electric generators; i.e., the number of active electric power generators is related to the total load drawn by the plurality of electrically powered devices. An example of such an industrial power system is a dynamic positioning thruster system used on a mobile offshore drilling platform. Depending on motion of the water, at any time only a subset of a total number of electrically powered thrusters used to maintain vessel position may be active. In such circumstances, fewer than the total number of electric power generators may be active. Such arrangement increases efficiency of electric power generation and consumption.

Electric power systems such as the foregoing may include isolation devices such as circuit breakers to disconnect each of the electric power generators and/or electrical loads from the power distribution circuits in the event of a fault in one or more parts of the power distribution circuits, the power generators or the electrical loads. Such isolation devices enable disconnection of the fault from the power distribution circuits, and as needed, engagement of one or more of the idle electric power generators so that the disconnected portions of the power system can still operate normally.

For applications where it is critical that faults do not spread to other connected parts of an electrical power system, such isolation capability is critical. Power systems for dynamically positioned vessels as explained above are one such critical application; in these systems loss of multiple parts of the electrical power system could result in complete loss of station keeping.

It has proven difficult to test the operation of circuit isolation devices under short circuit conditions, particularly symmetrical, three phase AC short circuit conditions. This is because such tests result in very high current, which can be damaging to electrical equipment, including the isolation devices themselves. Because of the difficulty in testing, some industrial electric power systems, such as those described above (e.g., dynamic positioning systems in which multiple distribution system failures may result from isolation device failure) are run in inefficient, open bus configuration in which sections of the power distribution system are isolated from each other all the time. Such configuration may result in increased fuel costs, increased maintenance cost and increased pollution.

There is a need for a device that enables testing of one or more circuit isolation devices in an interconnected electric power distribution system without applying a short circuit to any part of the power distribution system.

### SUMMARY

A circuit testing apparatus according to one aspect of the disclosure includes at least one resistance wire enclosed in a housing and connectable to a pole of a power distribution system having at least one isolation device therein. The resistance wire has electrical conductivity, length and diameter such that a maximum current in the resistance wire at initiation of burn through of the resistance wire is above a trip current of the at least one isolation device and below a current sufficient to damage any component along the pole of the power distribution system.

In some embodiments, the housing comprises a vent arranged to enable escape of heated gas therefrom and prevent escape of any hot particles resulting from burh through of the resistance wire.

In some embodiments, the vent comprises a tortuous path baffle system.

In some embodiments, the vent comprises a perforated, electrically non-conductive tube surrounding the resistance wire and a perforated, sand filled tube surrounding the perforated, electrically non-conductive tube.

In some embodiments, the at least one resistance wire comprises nichrome wire.

Some embodiments further comprise three resistance wires each connectable to a respective pole of a three-phase, wye-connected AC power distribution system.

In some embodiments, the vent comprises a perforated, electrically non-conductive tube surrounding each resistance wire and a perforated, sand filled tube surrounding each perforated, electrically non-conductive tube.

In some embodiments, the at least one isolation device comprises a circuit breaker.

A method for testing a power distribution system according to another aspect of the present disclosure includes connecting at least one resistance wire enclosed in a housing to a pole of a power distribution system having at least one isolation device therein. The resistance wire has electrical conductivity, length and diameter such that a maximum current in the resistance wire at initiation of burn through of the resistance wire is above a trip current of the at least one isolation device and below a current sufficient to damage any component along the pole of the power distribution system. Operation of the at least one isolation device is observed.

In some embodiments, the housing comprises a vent arranged to enable escape of heated gas therefrom and prevent escape of any hot particles resulting from burn through of the resistance wire.

In some embodiments, the vent comprises a tortuous path baffle system.

In some embodiments, the vent comprises a perforated, electrically non-conductive tube surrounding the resistance wire and a perforated, sand filled tube surrounding the perforated, electrically non-conductive tube.

In some embodiments, the at least one resistance wire comprises nichrome wire.

Some embodiments further comprise three resistance wires each connectable to a respective pole of a three-phase, wye-connected AC power distribution system.

In some embodiments, the vent comprises a perforated, electrically non-conductive tube surrounding each resistance wire and a perforated, sand filled tube surrounding each perforated, electrically non-conductive tube.

In some embodiments, the at least one isolation device comprises a circuit breaker.

### BRIEF DESCRIPTION OF THE DRAWINGS

FIG. 1A shows a side view of an example embodiment of a circuit testing apparatus according to the present disclosure.

FIG. 1B shows a top view of the circuit testing apparatus shown in FIG. 1A

FIG. 1C shows another example embodiment of a circuit testing apparatus according to the present disclosure.

FIG. 2 shows a graph of current with respect to time passing through a circuit testing apparatus according to the present disclosure.

### DETAILED DESCRIPTION

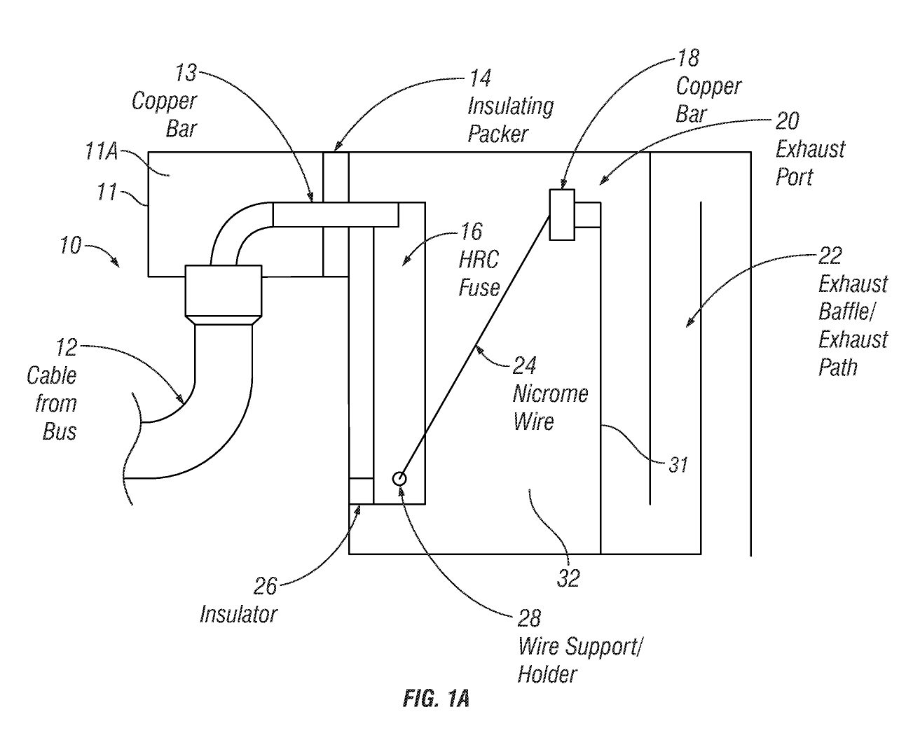

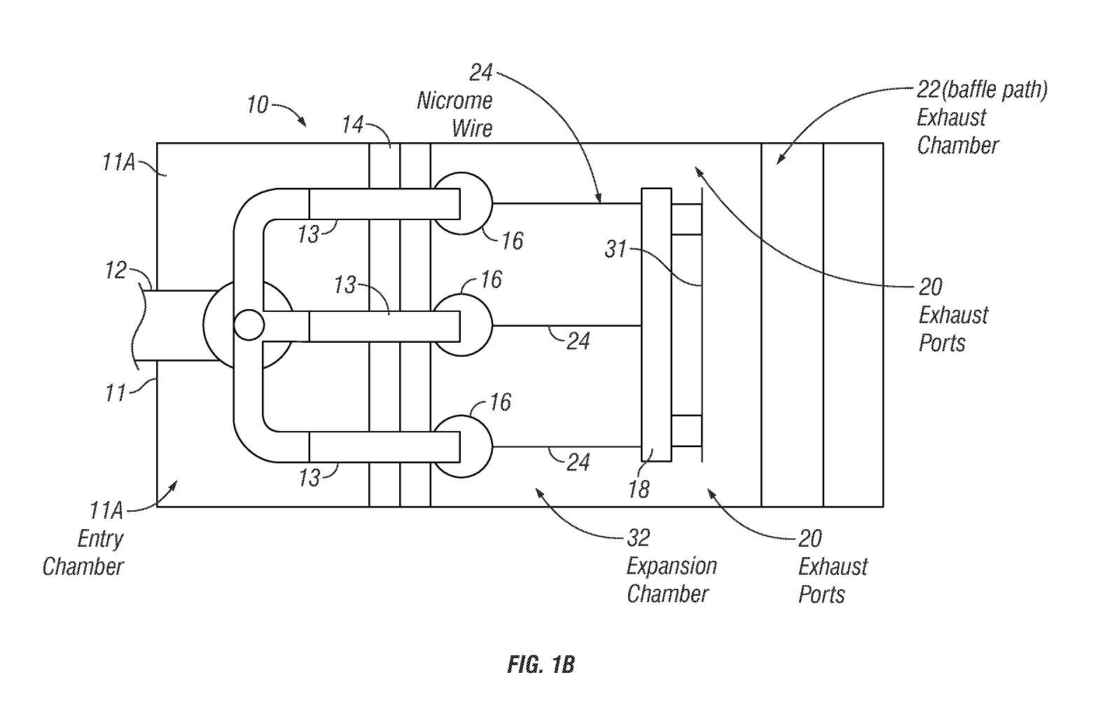

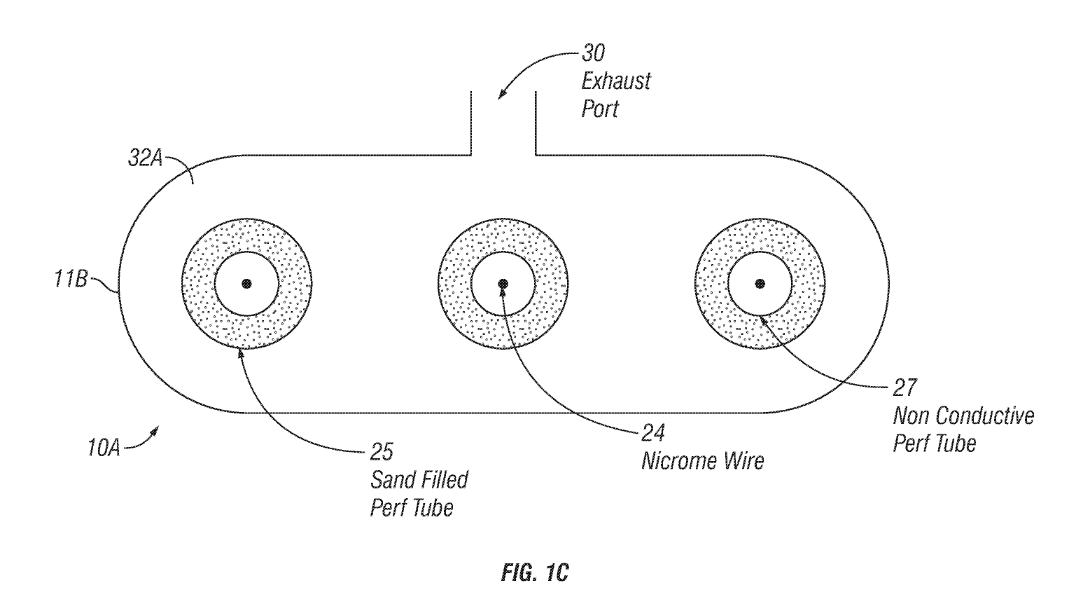

FIG. 1A shows a schematic top view of an example embodiment or a circuit testing apparatus according to the present disclosure. The circuit testing apparatus 10 comprises an electrical power connection, e.g., a cable 12 that is connectable to an electrical power system bus (not shown in the figures). Components of the circuit testing apparatus connected to the cable 12 may be disposed in an enclosed housing 11 as will be further explained below. The cable 12 may comprise one insulated electrical conductor (omitted for clarity) connectable to each pole of the electrical power system bus, in the present embodiment three insulated electrical conductors. The present example embodiment may be used with three-phase, wye-connected AC power bus, although any other connection for multiple phases may be used in connection with a device according to the present disclosure. Other embodiments may have more or fewer insulated electrical conductors, depending on the number of electrical poles in the particular circuit bus.

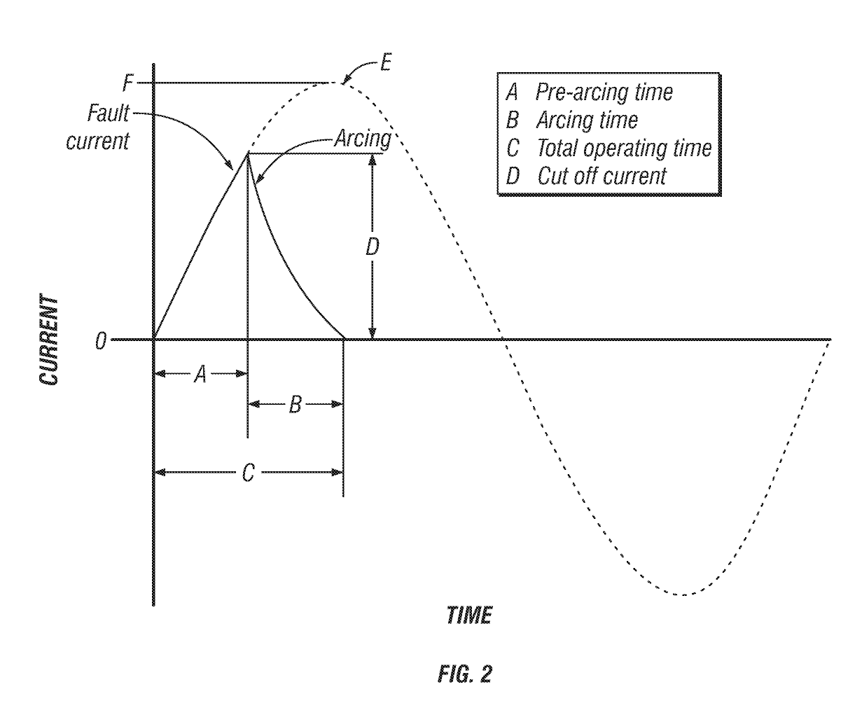

The cable terminates in an electrically conductive, e.g., copper bar 13 for each insulated electrical conductor. An entry chamber 11A in the housing 11 may provide an enclosed entry point for the cable 12. The copper bars 13 may exit the entry chamber 11A through a seal such as a packer 14 to isolate certain components of the circuit testing apparatus 10 from the cable 12 and the ambient atmosphere outside the housing 11. Each copper bar 13 may be electrically connected to one pole of a respective high rupture capacity (HRC) fuse 16. The HRC fuse 16 may be mounted to the housing 11 using at least one standoff insulator 26. The other pole of the HRC fuse 16 may be connected to one endo of a resistance wire 24, e.g., a nichrome wire. The resistance wire 24 may have diameter, length and electrical conductivity such that the resistance wire 24 will burn through, such as by partial or total vaporization at a selected electrical current (explained further below with reference to FIG. 2). The other end of the resistance wire 24 may be connected to a bus bar 18, such as a copper bus bar. The bus bar 18 may also be mounted to a baffle plate 31 in the interior of the housing 11. Enclosed space inside the housing 11 between the packer 14 and the baffle plate, shown as expansion chamber 32 may provide space for gases inside the housing 11 to expand when the resistance wire(s) 24 burn through. An exhaust port 20 may be disposed above the bus bar 18 to enable the expanding gases to exit the expansion chamber 32 into a tortuous path baffle system 22. The baffle system 22 provides a path for expanding gases to safely exit the interior of the housing 11 while reducing the possibility of any hot particles, e.g., bits of heated resistance wire from exiting the housing 11 and exposing the ambient atmosphere outside the housing 11 to an ignition source hazard.

FIG. 1B shows a top view of the example embodiment shown in FIG. 1A, wherein may be observed that there are three copper bars 13, one for each pole of the electrical circuit system power bus. FIG. 1B also shows connections between each copper bar 13, each HRC fuse 16, each resistance wire 24 and the bus bar

FIG. 1C shows another example embodiment of a circuit testing apparatus 10A which may include a cable 12, copper bars(s) 13 and HRC fuse(s) 16 as explained with reference to FIGS. 1A and 1B. In the present example embodiment, the housing (11 in FIG. 1A) may be substituted by an expansion housing 1A enclosing the resistance wire(s) 24. The example embodiment may provide for quenching products of burn through of the resistance wire(s) 24 in the form of enclosing the resistance wire(s) 24 in a perforated, electrically non-conductive tube 27 such as may be made from high temperature resistant plastic, polymer or the like. The perforated, electrically non-conductive tube 27 may be disposed within a sand-filled, perforated tube 25 made from any suitable material. Burn through products from the resistance wire(s) 24 may be discharged into the respective perforated, electrically non-conductive tube 27. Expanding gases may exit the perforated, electrically non-conductive tube 27 and enter the sand-filled perforated tube 25, where any hot particles may be stopped by the sand, such that only gases leave the sand-filled perforated tube 25. The expanding gases may enter the interior of the housing 32A. Such gases may be discharged into the ambient atmosphere through an exhaust port 30. Thus, the embodiment shown in FIG. 1C may enable gases to be safely vented to the ambient atmosphere without discharging hot particles thereto.

FIG. 2 shows a graph of current flow through the circuit testing apparatus with respect to time for one of the poles (e.g., on resistance wire/copper bar in FIG. 1B) to illustrate a result of suitable selection of material and dimensions of the resistance wire (24 in FIG. 1B) for an AC pole in a power distribution system. Curve E shows what the current would be for an ordinary short circuit fault across one pole in the power distribution system. The peak current F in the current curve E would be of such magnitude that within the trip time of any isolation device (e.g., a circuit breaker) that portions of the power distribution system subject to such peak current F may be susceptible to damage. By suitable selection of conductivity of the resistance wire (24 in FIG. 1B) and its dimensions (length, diameter), the maximum current flowing in the distribution system pole connected to the resistance wire (24 in FIG. 1B) may be limited to a chosen cutoff current D and such chosen cutoff current may be limited in duration to a pre-arcing time, shown at A. An arcing current may flow for an amount of time, shown at B, between initiation of burn through until insufficient amounts of the resistance wire remain to sustain the arc. At such time the current through the pole stops flowing entirely. Current flows for a total time shown at C. The current at the end of the pre-arcing time A may be chosen by suitable selection of the conductivity, length and diameter of the resistance wire (24 in FIG. 1B) such that any isolation device, e.g., a circuit breaker, will have operated at sufficient overload for a sufficient time to trip, but the value of current at the end of the pre-arcing time A is below an amount sufficient to cause any damage to components of the power distribution system. See, for example, Low voltage circuit breakers, Working with trip characteristic curves, ABB, Inc. Low Voltage Control Products & Systems, 1206 Hatton Road, Wichita Falls, Tex. 76302, publication no. 1SXU210170B0201 for a description of characteristic trip times with respect to overcurrent for certain types of circuit breakers.

Using the circuit testing apparatus as explained with reference to FIGS. 1A, 1B and 1C may comprise connecting the testing apparatus to at least one pole of a power distribution system downstream of any isolation device to be tested and switching on the connection from the pole to the testing apparatus. Any isolation device (or overcurrent protection device) if tripped before current stops flowing through any one or more poles of the power distribution system is deemed to be correctly functioning. In such event, the power distribution may be deemed to be protected from short circuit faults.

Although only a few examples have been described in detail above, those skilled in the art will readily appreciate that many modifications are possible in the examples. Accordingly, all such modifications are intended to be included within the scope of this disclosure as defined in the following claims.

What is claimed is:

1. A circuit testing apparatus, comprising:
at least one resistance wire enclosed in a housing and connectable to a pole of a power distribution system having at least one isolation device therein, the resistance wire having electrical conductivity, length and diameter such that a maximum current in the resistance wire at initiation of burn through of the resistance wire is above a trip current of the at least one isolation device and below a current sufficient to damage any component along the pole of the power distribution system.

2. The apparatus of claim 1 wherein the housing comprises a vent arranged to enable escape of heated gas therefrom and prevent escape of any hot particles resulting from burh through of the resistance wire.

3. The apparatus of claim 2 wherein the vent comprises a tortuous path baffle system.

4. The apparatus of claim 2 wherein the vent comprises a perforated, electrically non-conductive tube surrounding the resistance wire and a perforated, sand filled tube surrounding the perforated, electrically non-conductive tube.

5. The apparatus of claim 1 wherein the at least one resistance wire comprises nichrome wire.

6. The apparatus of claim 1 further comprising three resistance wires each connectable to a respective pole of a three-phase, wye-connected AC power distribution system.

7. The apparatus of claim 6 wherein the vent comprises a perforated, electrically non-conductive tube surrounding each resistance wire and a perforated, sand filled tube surrounding each perforated, electrically non-conductive tube.

8. The apparatus of claim 1 wherein the at least one isolation device comprises a circuit breaker.

9. A method for testing a power distribution system, comprising:
connecting at least one resistance wire enclosed in a housing to a pole of a power distribution system having at least one isolation device therein, the resistance wire having electrical conductivity, length and diameter such that a maximum current in the resistance wire at initiation of burn through of the resistance wire is above a trip current of the at least one isolation device and below a current sufficient to damage any component along the pole of the power distribution system; and
observing operation of the at least one isolation device.

10. The method of claim 9 wherein the housing comprises a vent arranged to enable escape of heated gas therefrom and prevent escape of any hot particles resulting from burn through of the resistance wire.

11. The method of claim 10 wherein the vent comprises a tortuous path baffle system.

12. The method of claim 10 wherein the vent comprises a perforated, electrically non-conductive tube surrounding the resistance wire and a perforated, sand filled tube surrounding the perforated, electrically non-conductive tube.

13. The method of claim 9 wherein the at least one resistance wire comprises nichrome wire.

14. The method of claim 9 further comprising three resistance wires each connectable to a respective pole of a three-phase, wye-connected AC power distribution system.

15. The method of claim 14 wherein the vent comprises a perforated, electrically non-conductive tube surrounding each resistance wire and a perforated, sand filled tube surrounding each perforated, electrically non-conductive tube.

16. The method of claim 9 wherein the at least one isolation device comprises a circuit breaker.
